(19) United States
(12) Patent Application Publication
(10) Pub. No.: US 2006/0097750 A1
(43) Pub. Date: May 11, 2006

(54) Electronic circuit with array of programmable logic cells

(76) Inventor: Katarzyna Leijten-Nowak, Eindhoven (NL)

Correspondence Address: Philips Electronics North America Corporation;Corporate Patent Counsel, PO Box 3001, Briarcliff Manor, NY, 10510, US

(21) Appl. No.: 10/520,441

(22) PCT Filed: Jul. 4, 2003
(86) PCT No.: PCT/IB03/02714

§ 371 Date: Sep. 1, 2005

(30) Foreign Application Priority Data
Jul. 10, 2002 (EP) 02077755.3

(51) Int. Cl. H03K 19/177; G06F 7/38; H01L 25/00

(52) U.S. Cl. 326/39; 326/41

(57) ABSTRACT

An electronic circuit has a programmable logic cell with a plurality of programmable logic units that are capable of being configured to operate in a multi-bit operand mode and a random logic mode. The programmable logic units are coupled in parallel between an input circuit and an output circuit. The input circuit can be configured to supply logic input signals from the same combination of the logic inputs to the programmable logic units in the random logic mode. In the multi-bit operand processing mode the input circuit is configured to supply logic input signals from different ones of the logic inputs to the programmable logic units. The programmable logic units are coupled to successive positions along a carry chain at least in the multi-bit operand mode, so as to process carry signals from the carry chain. The output circuit selects an output signal from the programmable logic units under control of further input signals in the random logic mode and passes outputs from the programmable logic units in parallel in the multi-bit operand mode.

The invention relates to an electronic circuit with an array of programmable logic cells.

Programmable logic cells enable circuit designers to adapt the logic function of individual instances of electronic circuits that have been mass-produced, such as integrated circuits. This reduces the time interval from design to production of a working circuit and it reduces manufacturing cost for production of small batches of products and for prototyping.

In one example of an implementation a programmable cell contains a memory that is addressed by the input signal of the cell and that stores pre-programmed output signals for each combination of input signal values at the respective addresses that are addressed by these values. The memory is said to have a LUT (Look-Up Table) function, for looking up the output signals that are produced in response to various input signals.

Any logic function can be implemented with a LUT, provided that it contains sufficient memory space. In practice, however, only logic functions that require a limited number of inputs, typically no more than four, are implemented with LUTs in circuits with programmable logic cells. Such a LUT requires 16 memory locations. This permits the programming of random logic functions of four input bits. In many cases circuits with such cells with four input bit functions suffice. A circuit with an array of such cells, in which the outputs of cells are coupled to the inputs of other cells, permits the designer to implement more complicated logic functions.

Increasingly designers implement logic functions for which a part of the array of programmable logic cells is used to implement signal processing operations such as additions. Many signal processing operations have the property that many bits of a wider input operand each can influence many bits in an output result, through carry effects. When such a wide dependency is implemented using 4 bit input LUTs very inefficient implementations are obtained.

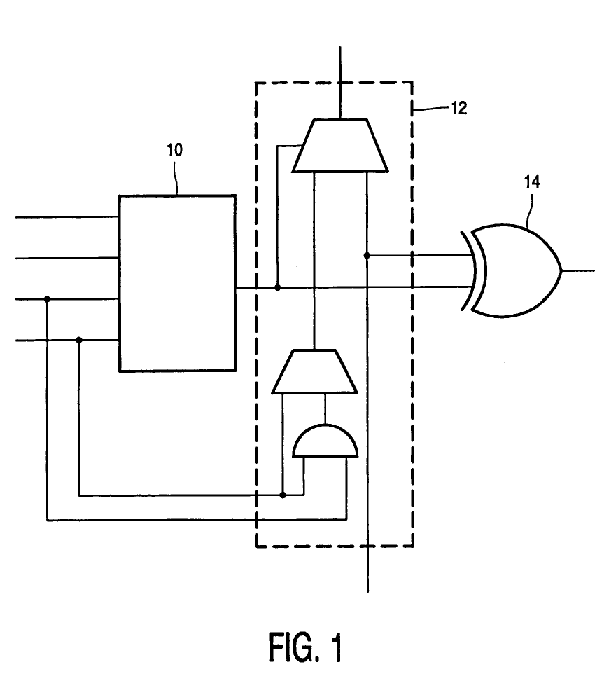

Xilinx has addressed this problem in its Virtex family of programmable logic devices by adding a carry chain to an array of 4 bit input LUT cells. FIG. 1 shows a programmable logic cell of such a device. The cell contains a four bit address memory 10 that performs the LUT function and a carry circuit 12 with a carry input and a carry output. The output of memory 10 is coupled to the carry circuit 12, which combines the carry input signal with the output signal of the LUT to form the carry output signal. An exclusive OR gate 14 is used to form the output signal of the cell from the carry input signal and output signal of the LUT. The carry input and carry output of the cell are coupled to the carry output and the carry input of adjacent cells in the array (not shown) to form a carry chain. The carry chain performs the carry function from the output of one 4 bit input LUT to another. As a result no LUTs need to be allocated to implement carry functions. This saves a considerable number of LUTs when the circuit is used to implement logic functions that include some signal processing operations.

Nevertheless, compared to dedicated signal processing circuitry, the implementation of signal processing functions in such a more general purpose circuit that is also capable of implementing random logic functions is still far less efficient. It would be desirable if this efficiency could be improved.

This holds as well for programmable logic circuits that use programmable elements other than memories that implement LUTs. More generally the logic function of programmable logic cells is controlled by the value of a set configuration bits in the circuit.

The value of the configuration bits can be set for example in memory elements, or programmed irreversibly by techniques such as the blowing of fuses. The content of a LUT may be set by configuration bits, but inputs to logic gates or control signals for logic circuits may also be set by configuration bits. The number of configuration bits is an important design parameter in these electronic circuits. A large number of configuration bits generally permits a wide scope for programming the circuit, but the need to store a large number of bits also makes the circuit more expensive and its response potentially slower. It has been found that the implementation of signal processing operations in these circuits either requires cells with a large number of configuration bits or more cells that each have fewer configuration bits. It would be desirable if this efficiency could be improved.

Among others, it is an object of the invention to provide for an electronic circuit with an array of programmable logic cells that permit the implementation of both random logic functions and signal processing operations in which efficient use is made of configuration bits.

The electronic circuit according to the invention is set forth in Claim 1. The electronic circuit contains a programmable logic cell with a plurality of programmable logic units that are coupled in parallel between signal inputs and outputs of the cell. The programmable logic cell is configurable to operate in a random logic mode and in a multi-bit operand mode. In the multi-bit operand mode different programmable logic units in the cell each receive input signals from the signal inputs of the cell and the outputs of the programmable logic units are supplied to the outputs of the cell in parallel. Carry signals propagate between the programmable logic units. In the random logic mode each of the programmable logic units in the cell receives the same signals from the signal inputs of the cell; further signals from the signal inputs select which of the programmable logic units has an output coupled to an output of the cell.

Thus, the cell can be programmed to perform both random logic functions and multi-bit signal processing operations with a small number of configuration bits for the programmable logic units. With four two-input programmable logic units for example, the cell can be configured to implement four bit significance levels of a signal processing operation, as well as a 4-bit input random logic operation (two of the input bits being supplied to each of the programmable logic units and the remaining two bits selecting which programmable logic unit is used to supply the output signal). This configurability is fully realized with only sixteen bits for programming the programmable logic units of the cell.

In an embodiment, the effect of the carry signal on at least one of the programmable logic units is implemented by means of a dedicated circuit that inverts the output signal of the programmable unit or not, dependent on the carry signal. The dedicated circuit typically has an exclusive OR functionality. Thus, no configuration bits are needed to implement the effect of carry.

In further embodiments, the cell may include circuits for configuring the operation of the carry chain, at least so as to determine carry signals as appropriate for subtraction and addition. Furthermore, a circuit for multiplying each of the bits of the multi-bit operand in the cell with the same mutiplicand may be provided. The input circuit may provide only a limited choice of couplings between the signal inputs of the cell and the inputs of the programmable logic units, including the couplings used for multi-bit operand signal processing and for computing a random logic function. By providing only a limited choice, the number of configuration bits that is needed to configure the input circuit can be reduced, without affecting the capability of configuring the cell to implement multi-bit signal processing and random logic functions.

In yet another embodiment, the cell supports configuration of a multiplexer function in a multiplexer mode, using circuitry that is used to account for the carry signals in the multi-bit operand mode.

The invention also relates to programmable circuits of this type that have been configured to perform multi-bit operand functions, random logic functions and multiplexer functions respectively.

These and other objects and advantageous aspects of the invention will be described using the following Figures.

FIG. 1 shows a prior art programmable logic cell;

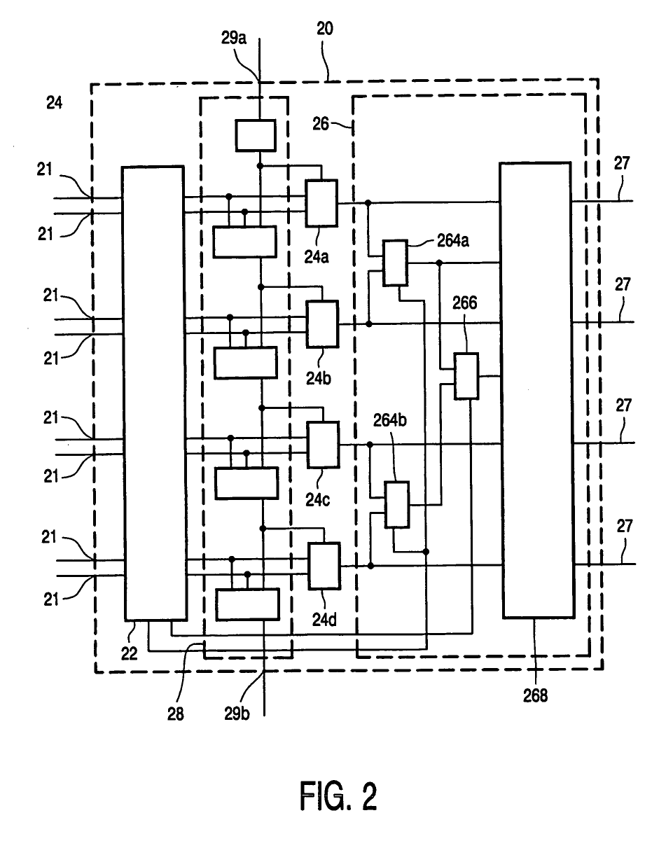

FIG. 2 shows a programmable logic cell according to the invention;

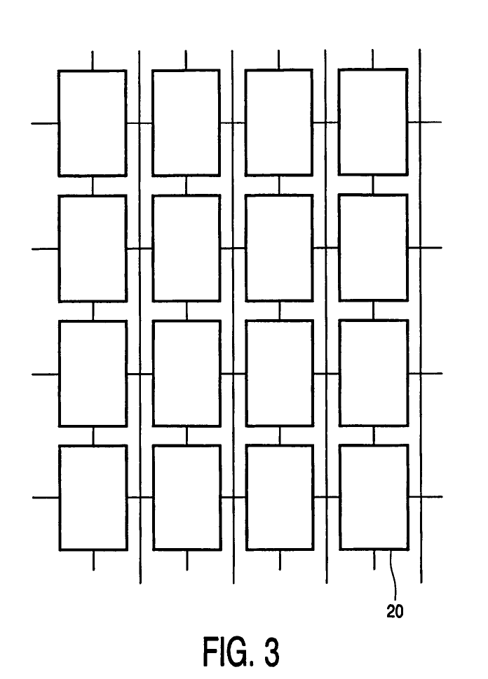

FIG. 3 shows an array of logic cells;

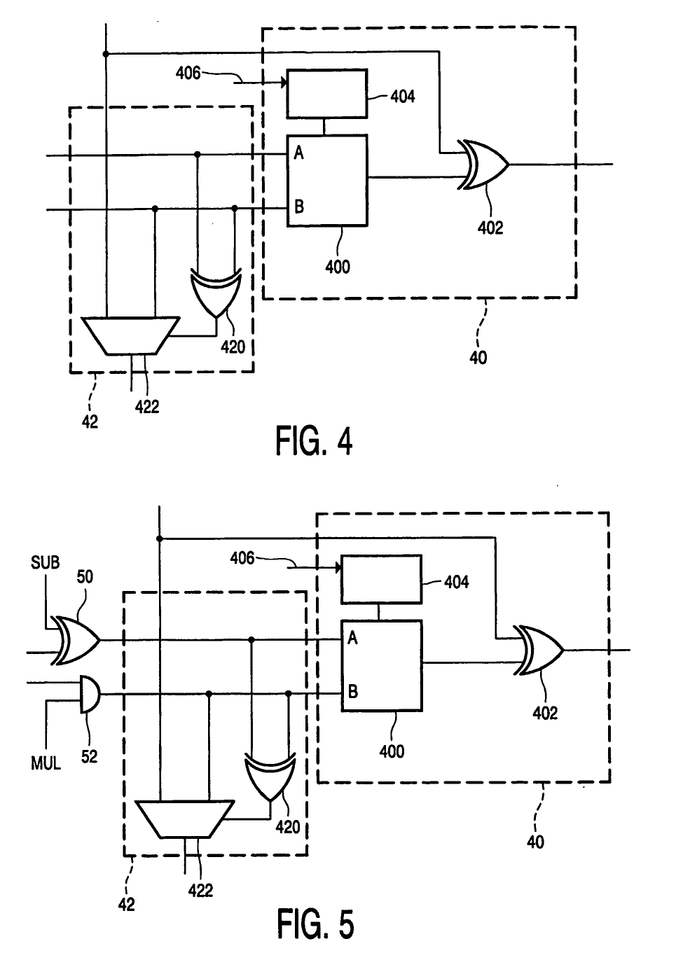

FIG. 4 shows a programmable logic unit and part of carry chain;

FIG. 5 shows modifications of the circuit of FIG. 4;

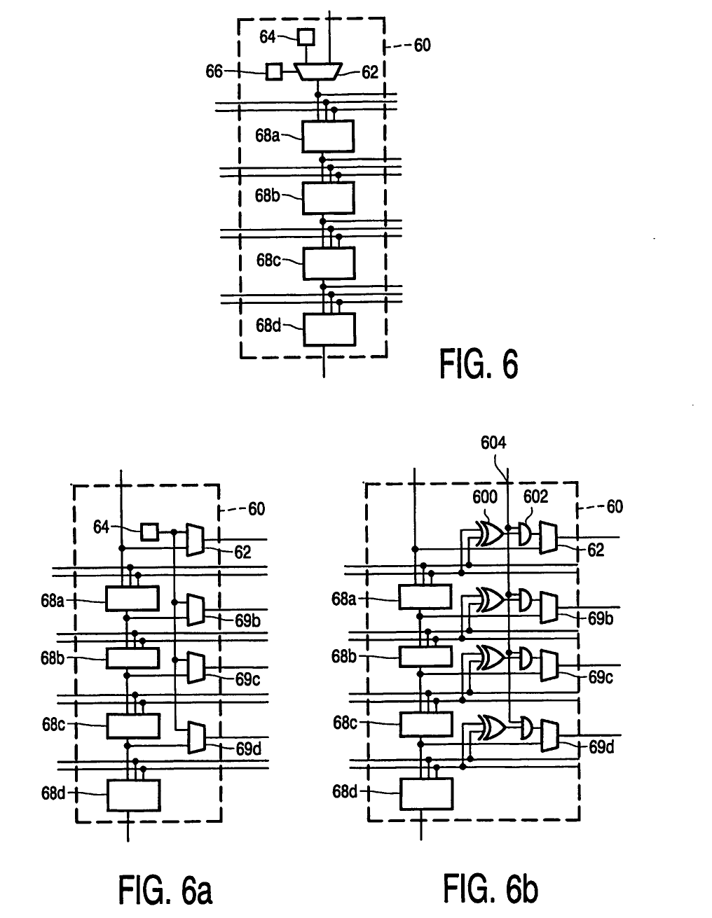

FIG. 6 shows a carry chain;

FIG. 6a shows an alternative carry chain;

FIG. 6b shows another alternative carry chain; and

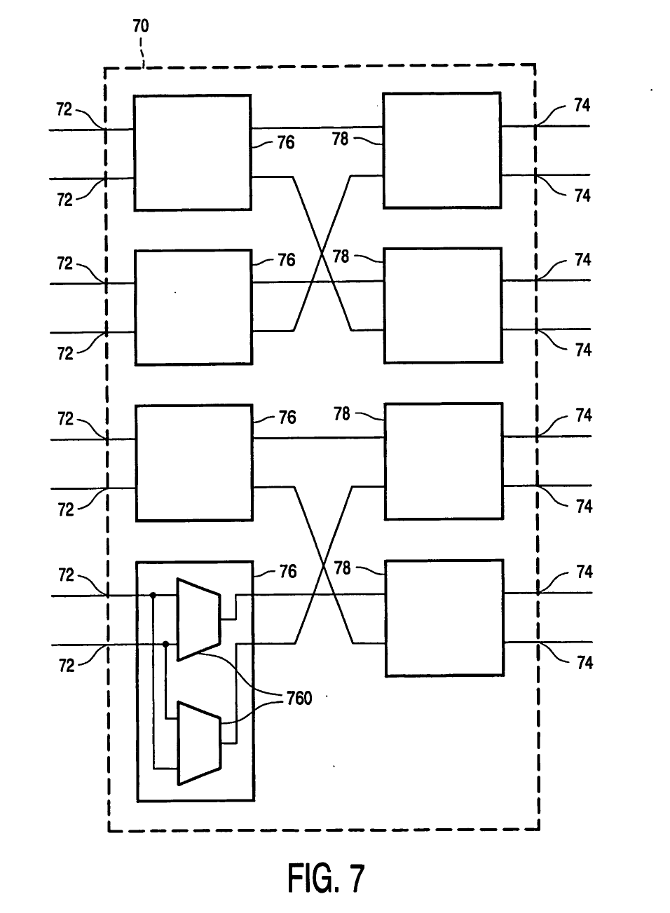

FIG. 7 shows an input circuit.

FIG. 2 shows a programmable logic cell 20. Cell 20 contains an input circuit 22, a plurality of programmable logic units 24a-d, an output circuit 26 and a carry chain 28. Signal inputs 21 and signal outputs 27 of the cell 20 are coupled via a cascade of input circuit 22, a parallel arrangement of programmable logic units 24a-d and output circuit 26. Carry chain 28 has a carry input 29a and a carry output 29b and is coupled to the programmable logic units at a series of positions along the chain.

Output circuit 26 contains a number of stages of multiplexers 264a, b, 266 and a switching stage 268. Control inputs of the multiplexers 264a, b in the first stage are coupled to a respective output of input circuit 22. Signal inputs of the multiplexers 264a, b of a first stage are coupled to the outputs of pairs of programmable logic units 24a-d, signal inputs of the multiplexer 266 at the second stage are coupled to the outputs of the multiplexers 264a, b of the first stage.

The outputs of the programmable logic units 24a-d and the multiplexer 266 of the second stage are coupled to inputs of the switching stage 268. Outputs of switching stage 268 are coupled to signal outputs 27 of cell 20. Switching stage 268 is configurable to couple either the outputs of the programmable logic units 24a-d to outputs 27 or the outputs of the multiplexers 264a, b, 266 of the first and second stage to outputs 27, or at least the output of multiplexer 266 of the second stage. Switching stage 268 may be provided with latches (not shown) for latching the output signal, so that cell 20 can function as final part of a pipelined stage in a pipelined circuit. Preferably, switching stage 268 is configurable to pass signals either after latching or without latching.

Cell 20 has been designed to enable designers to configure cell 20 to implement a selected input-output function. By programming configuration bits of programmable logic units 24a-d, input circuit 22, output circuit 26 and carry chain 28, the function of cell 20 can be configured. (The configuration bits are stored in configuration memories (not shown) which are loaded via a programming path (not shown), both of which are known per se for programmable logic devices). The configuration bits determine which of signal inputs 21 are coupled to which of programmable logic units 24a-d, the configuration bits determine which output signal values the programmable logic units 24a-d will produce in response to various input signal values, the configuration bits determine which signals switching stage 268 will pass to signal output 27 and the configuration bits determine whether a carry input signal from carry input 29a will be passed into cell 20. In operation cell 20 can be configured to function in a random logic mode and in a multi-bit operand processing mode. In operation, the multi-bit operand mode cell 20 outputs a plurality of bits of an output result that depends on input operands with a plurality of bits. The bits in each input operand have successively higher significance levels. In the multi-bit operand mode each programmable logic unit 24a-d is associated with a different significance level. The input circuit 22 is configured to pass signals to each programmable logic unit 24a-d that represent the bits from different operands, each bit corresponding to the significance level that is associated with the programmable logic unit 24a-d. Each programmable logic unit 24a-d responds to these signals by computing the bit of the result at the significance level that is associated with the programmable logic unit 24a-d, taking account of a carry in signal that is received from carry chain 28 from a lower significance level and supplying a carry out to the carry chain for use at a higher significance level. In the multi-bit operand mode, all programmable logic units 24a-d will generally be configured to provide the same relation between their input signals and output signals. Output circuit 26 is configured to pass the computed bits of the result from all of the programmable logic units 24a-d in parallel as output signals to output 27.

Carry chain 28 computes carry signals and passes these carry signals from one programmable logic unit 24a-d to another. The configuration of carry chain 28 controls whether carry chain 28 uses a carry input signal from carry input 29a to determine the carry signals. If cell 20 processes input signals that are more significant bits of a larger operand, the cell is configured so that such a carry input signal is used to receive a carry output signal of another cell that processes less significant operands.

FIG. 3 shows a two dimensional array of cells 20 of the type shown in FIG. 2. The array is organized as a matrix with rows and columns of cells 20. Signal inputs, signal outputs, carry inputs and carry outputs of adjacent cells are coupled to each other. Furthermore busses are provided to enable couplings between non-adjacent cells 30. (Connections between the cells and busses are shown schematically with single crossing lines only for the sake of clarity). In an array of this type any combination of random logic functions and multi-bit signal processing operations can easily be implemented.

In operation in the random logic mode the output signal of cell 20 is a random logic function of a number of input signals. This random logic function is implemented using programmable logic units 24a-d and the first and second stages of multiplexers 264a, b, 266. Input circuit 22 passes the same input signals to each of the programmable functional units 24a-d. Under control of other ones of the input signals multiplexers 264a, b, 266 select one of the programmable logic units 24a-d from which the output signal is passed to switching stage 268, a first of these other ones of the control signals controls both multiplexers 264a, b in the first stage, a second of these other ones of the control signals controls multiplexer 266 in the second stage, which selects between the outputs of multiplexers 264a, b in the first stage. Thus, a logic function is realized that depends both on the input signals of the programmable logic units 24a-d and on the other ones of the input signals that control multiplexers 264a, b, 266. Each of the programmable functional units 24a-d produces an output signal in response to the same input signals, each for use as output signal for a different value of the other ones of the input signals. Switching stage 268 passes the resulting output signal from multiplexer 266 to the signal output of cell 20.

Carry chain 28 is configured so that no external carry input signal is used in the random logic mode. Dependent on the implementation of carry chain 28, carry chain 28 may still pass some carry signals, which arise at certain input values of the inputs to programmable logic units 24a-d. In this case, the configuration of programmable logic units 24a-d further down the carry chain may be adapted to account for the presence of carry signals for specific values of the input values. In an alternative implementation of carry chain 28, multiplexers may be included in the carry chain, which pass either the carry signal from a previous significance level in the multi-bit operand mode or a predetermined signal (e.g. zero for all significance levels) in the random logic mode. In this embodiment, the configuration of programmable logic units 24a-d need not be adapted to account for the presence of signal dependent carry signals.

Thus there is a contrast between the random logic mode and the multi-bit operand mode. On one hand, in the random logic mode, each programmable logic unit 24a-d receives the same input signals and each provides a potentially different input-output function for a different value of the other ones of the input signals that control the multiplexing stages 260, 262. On the other hand, in the multi-bit operand mode, the programmable logic units 24a-d receive different input signals, but generally provide the same input-output function.

By using the programmable logic units alternatively on one hand for implementing computation of different significance levels of a two multi-bit operand signal processing operation and on the other hand as part of a structure for computing a more than two bit-input random logic function, the number of configuration bits that is needed to support implementation of both random logic functions and multi-bit operand signal processing is minimized. In the example of FIG. 2, with four two input programmable logic units 24a-d, which are fully programmable with four configuration bits each, sixteen bits suffice to define any four bit-input random logic function and at the same time four significance levels of any two-operand signal processing operation. In contrast, consider the situation where four bit input programmable logic units 24a-d would have been used (each of which requires 16 configuration bits for full programming). Such programmable logic units could perform a computation at two significance levels of a multi-bit operand signal processing operation, but this would require twice as many configuration bits per significance level.

In a further embodiment, cell 20 is arranged so that is also configurable to produce the result of two random logic functions of three input bits. In this case, the outputs of multiplexers 264a, b of the first stage of output circuit 26 are used as outputs of cell. Since cell 20 has four outputs for passing four bits of a multi-bit result, these results from the outputs of multiplexers 264a, b can be passed in parallel with the output signal from multiplexer 266 in the second stage.

In this further embodiment, cell 20 is preferably arranged so that it can be configured so that the input signals of the two random logic functions come from different ones of the inputs 21, or at least can be selected to come from different ones of the inputs. That is, two of the programmable logic units 24a, b receive the same pair of input signals and the two other programmable logic units 24c, d receive another pair of input signals. For this purpose, input circuit 22 is preferably arranged so that it can be configured to select these pairs independently. Furthermore, under a control of a configuration bit, the control signal of multiplexer 266 in the second stage of output circuit 26 is fed to one of multiplexers 264a, b of the first stage. Thus, selection by multiplexers 264a, b is also controlled by independently selected bits. The operation of cell 20 in this third mode (two 3 bit input random logic functions) is between the random logic mode and the multi-bit operand mode, in that programmable logic units 24a-d partly receive the same signals and partly receive different signals and in that two output signals are produced.

FIG. 4 shows an embodiment of a programmable logic unit 40 together with part of a carry chain 42. Programmable logic unit contains a LUT unit 400, a configuration memory 404 and a first exclusive OR gate 402. The part of carry chain 42 contains a second exclusive OR gate 420 and a multiplexer 422. The signal inputs A, B of programmable logic unit 40 are coupled to the inputs of LUT unit 400. Configuration memory 404 is also coupled to LUT unit 400. An output of LUT unit 400 is coupled to an input of first exclusive-OR gate 402. A second input of first exclusive OR-gate 402 is coupled to a carry input of the carry chain 42 and an output of first exclusive OR gate 402 forms an output of programmable logic unit 40. The signal inputs A, B of programmable logic unit 40 are coupled to inputs of second exclusive OR gate 420, which has an output coupled to a control input of multiplexer 422. Multiplexer 422 has inputs coupled to the carry input and to one of the signal inputs of programmable logic unit 40 respectively. The combination of LUT unit 400 and configuration memory 404 may be implemented as a number of memory cells for configuration bits with a multiplexing structure that selects an output of one of the memory cells under control of signals from the signal inputs, and outputs the content of the selected memory cell from the LUT unit 400. A conventional 4-bit memory structure may be used for this purpose. Configuration memory 404 has an input 406 for loading configuration bits into configuration memory 404 via a conventional configuration path (not shown).

In operation LUT unit 400 realizes a configurable input output function. In response to each possible combination of input signals A, B LUT unit 400 outputs a respective output signal that is selected by the input signals. Each combination of input signals has an output signal assigned to it by configuration bits that are stored in configuration memory 404. Four configuration bits are sufficient to make it possible configure any possible assignment. Through the action of exclusive OR gate 402 a copy of the output signal of LUT unit 400 is output from programmable logic unit when the carry input signal is logic low and an inverted copy of the output signal is output if the carry input signal is logic high. The carry output signal is determined from the carry input signal and the input signals A, B of programmable logic unit. When the input signals A, B are equal multiplexer 422 outputs one of the input signals A as carry output signal and when the input signals A, B are not equal multiplexer 422 outputs the carry input signal as carry output signal.

It will be clear that several alternative embodiments of programmable logic unit exists that have the same logic function. As an alternative, for example, the function of programmable logic unit 40 could be implemented with a three input LUT unit (not shown) that receives the carry signal in addition to the input signals A, B at its inputs and generates a configurable output signal. However, such a LUT unit would need eight configuration bits to be fully programmable. The use of first exclusive OR gate 402 to effect carry makes it possible to program both any random two-bit logic function and a signal processing operation that involves a carry with no more than four configuration bits in LUT unit 400. Similarly, determination of the carry output signal could have been implemented with a further LUT (not shown), be it at the expense of further configuration bits. But even when implemented with hard-wired circuitry several alternative embodiments of the computation of the carry signal are possible, of course, using logic circuitry with the same input output function as the circuitry shown in FIG. 4.

With the circuit of FIG. 4 an arithmetic addition operation may be implemented by programming the configuration bits of LUT unit 400 to perform an exclusive OR function. Operations other than addition may be implemented by programming LUT unit 400 differently and of course addition of a first and second operand is equivalent to subtraction of the complement of the second operand from the first operand, when a logic high carry input signal is used at the lowest significance level.

FIG. 5 shows some additions to the combination of carry chain 42 and programmable logic unit 40 to adapt it to perform arithmetic subtraction without external complement formation and 1-bit multiplication-plus-accumulation (e.g. as a step in multi-bit multiplication). Implementation of subtraction is facilitated by adding an exclusive OR gate 50 between on one side the LUT unit and second exclusive OR gate and on the other side one of the signal inputs A, B that receives a bit of the operand that must be subtracted. A subtraction control signal is supplied to one of the inputs of exclusive OR gate 50 so that the input signal is logically inverted. The subtraction control signal is set to zero when addition is required. A common subtraction control signal for all of the programmable logic units in cell 20 may be used for this purpose. The subtraction signal may be controlled by a configuration bit of cell 20 or by a signal from outside cell 20. In case of subtraction a logic high carry input signal is applied to the programmable logic unit that is associated with the lowest significance level.

Implementation of multiplication plus accumulation is supported by adding an AND gate 52 between on one side the LUT unit and second exclusive OR gate and on the other side one of the signal inputs A, B that receives a bit of the operand that must be multiplied and supplying a factor signal to one of the inputs of this AND gate. A common factor signal for all of the programmable logic units in cell 20 may be used for this purpose. The factor signal is set to one when addition is required.

As shown AND gate 52 and the exclusive OR gate 50 may be provided in combination, but of course either may be omitted when no subtraction or multiplication is required. Also, it will be understood that multiplication and subtraction can be implemented in alternative ways, with equivalents of exclusive OR gate 50 at different positions in the circuit and/or a different configuration of LUT unit 400. For example, exclusive OR gate 50 may be coupled between an output of the input circuit and the input of carry chain 42, the output of the input circuit being coupled to programmable logic unit 40 without passing through exclusive OR gate 50, provided that the configuration bits in programmable logic unit 40 are adapted to the absence of the effect of exclusive OR gate 50 in case of subtraction. In this case, however, the configuration of programmable logic unit needs to be changed when one switches from addition to subtraction.

FIG. 6 shows a carry chain 60 of a cell 20 in more detail. Carry chain 60 contains an input multiplexer 62, a carry input configuration memory 64, a selection configuration memory 66 and a plurality of carry logic units 68a-d. The carry input of cell 20 and carry input configuration memory 64 are coupled to signals inputs of multiplexer 62. Selection configuration memory 66 is coupled to a control input of multiplexer 62. An output of multiplexer 62 is coupled to a cascade of carry logic units 68a-d, which have inputs coupled to the inputs A, B of each of the programmable logic units 24a-d and outputs coupled to those programmable logic units 24a-d. The content of carry input configuration memory 64, selection configuration memory 66 is programmable via configuration paths (not shown).

In operation, the selection configuration memory 66 selects between using a carry input signal from outside cell 20 and using a carry input content from carry input configuration memory 64. The latter is selected in a random logic mode of operation of the cell, and in a multi-bit operand mode of operation when cell 20 has to process the least significant bits of the multi-bit operand. The carry input content from carry input configuration memory 64 is set according to the needs of the desired multi-bit operand operation or to a level appropriate to the random logic operation. In the latter case, when each of programmable logic units 24a-d receives the same input signals A, B, programmable logic units 24a-d are programmed so as to account for the effect of carry signals from the carry chain.

FIG. 6a shows an alternative carry chain in which carry logic units 68a-d implemented with a configurable carry suppression circuit, for example a multiplexer 69a-d that either couples the carry output of carry logic circuit 68a-c to the carry signal input of the programmable logic units (not shown) or couples a source of a predetermined signal value, for example configuration memory 64 or a hardwired logic zero to the carry signal input of the programmable logic units. The carry suppression circuit is controlled by a configuration bit that controls whether the circuit operates in the random logic mode or the multi-bit operand mode. The carry suppression circuit replaces the carry signal that is fed to the programmable logic units with a signal that has the predetermined logic level when the circuit is configured in the random logic mode. Thus no carry propagation affects cell 20 in the random logic mode. This makes the circuit faster and less prone to generate glitches in the output signals. In this case, when in the random logic mode, the programmable logic units 24a-d are all programmed to perform the same logic function given that predetermined carry input signal. Although multiplexers 69b-d have been shown between the carry chain and the programmable logic units, they may of course also be included in the path between successive carry logic circuits 68a-d. In this case, these carry logic circuits 68a-d are also not affected by carry propagation.

Multiplexer functions require a relatively large number of inputs: the smallest possible multiplexer requires three inputs, two for signals and one for control. A four way multiplexer requires six inputs. Due to the large number of inputs configuration of programmable cells to implement a multiplexer function is therefore normally inefficient.

FIG. 6b shows a modification of the carry chain of FIG. 6a that supports configuration of the cell as a multiplexer. A cascade of an exclusive OR gate 600 and an AND gate 602 has been added at the input of each of multiplexers 62, 69b-d. The inputs of each of the exclusive OR gates 600 are coupled to respective signal inputs A, B and the output of the exclusive OR gates are coupled to inputs respective ones of the AND gates 602. The output of the AND gates are coupled to the first inputs of multiplexers 62, 69b-d that receive the predetermined signal in FIG. 6a. Second inputs of the AND gates are coupled in common to an auxiliary input 604.

In operation exclusive OR gate 600 and an AND gate 602 support configuration of the cell as a multiplexer. When the cell is configured as a multiplexer, its operation is a mixture of operation in the multi-bit operand mode and operation in the random logic mode. Input circuit 22 passes the different input signals to each of the programmable functional units 24a-d, as in the multi-bit operand mode. Each programmable logic unit is configured to implement the same logic function, also as in the multi-bit operand mode. Under control of other ones of the input signals multiplexers 264a, b, 266 select one of the programmable logic units 24a-d from which the output signal is passed to switching stage 268, as in the random logic mode. Each of the programmable logic units 24a-d is to implement a 2:1 multiplexer function under control of a signal at the auxiliary input 604. For this purpose, the programmable logic units are configured to reproduces the value of one of their input signals A, B (say A) at their output. When the signal at the auxiliary input 604 is zero this signal is passed to the output of exclusive OR gate 402. When the signal at the auxiliary input 604 is one, the signal at the output of exclusive OR gate 402 is inverted if the input signals A, B are unequal (as signaled by exclusive OR gate 600), i.e. the copy of signal A is inverted to equal the signal B. In all the output signal of exclusive OR gate 402 is
output=EXOR(A,C*EXOR(A,B))

Here C is the signal at the auxiliary input 604. This is a 2:1 multiplexer function. In combination with selection by multiplexers 264a, b, 266 an 8:1, or a pair of 4:1 multiplexer functions is realized. Advantageously exclusive OR gate 420 of carry chain 42 may be used to perform the function of exclusive OR gate 600. As signal at the auxiliary input 604 an input signal of the cell can be used, or the control signal that is used to select between addition and subtraction may be used.

Of course, configuration of the programmable logic units may be used to combine multiplexing functions with some logic operations, for example to switch the role of the A and B inputs.

FIG. 7 shows an input circuit 70. Input circuit 70 has a plurality of inputs 72 coupled to inputs of cell 20 and a plurality of outputs 74 coupled to the inputs of programmable logic units 24a-d and to multiplexers in the output circuit of cell 20. The inputs 72 and outputs 74 are coupled via two layers of switching circuits 76, 78. The switching circuits may be implemented using two multiplexers 760 in each switching circuit 76, 78 (only one shown in detail), each multiplexer 760 providing a configurable coupling from each input of the switching circuit to a respective one of the outputs. Input circuit 70 also contains third multiplexers (not shown) for selecting input signals that are fed to the multiplexers 264a, b, 266 of the output stage. The operation of switching circuits 76, 78, and the third multiplexers is controlled by configuration bits from configuration memories (not shown).

Both layers 76, 78 are organized as groups of switching circuits 76, 78 each coupling a respective pairs of that inputs to a respective pair of outputs, and are arranged so that the switching circuits 76, 78 in each group are capable of configurably switching between on one hand copying signals from each one of the pair of inputs to both outputs of its pair of outputs, and on the other hand coupling the signals from each input of the pair of inputs to respective ones of the pair of outputs. Layers 76, 78 are combined in series, with outputs from pairs of switching circuits 76 of the first layer being coupled cross-wise to inputs of a pair of different switching circuit 78 in the second layer 78. As a result layers 76, 78 couple quadruplets of inputs 72 to respective quadruplets of outputs 74, and are capable of configurably switching between copying signals from each one of the quadruplet of inputs 72 to all of the outputs in the corresponding quadruplets of outputs 74, and coupling respective ones of the quadruplet of inputs to respective ones of the quadruplet of outputs.

Cell 20 has configuration memories (not shown) coupled to control inputs of switching circuits 76, 78, so that the content of the configuration memories controls switching of the multiplexers of the input circuit. The configuration memories at least select between a random logic mode and a multi-bit operand mode. In the random logic mode switching circuits 76, 78, are controlled to copy signals from two of inputs 72 are copied to inputs of each of the programmable logic units and the third multiplexers (not shown) are controlled to couple signals from other ones of the inputs to control inputs of multiplexers in the output circuit. In the multi-bit operand mode switching circuits 76, 78, are controlled to couple respective ones of inputs 72 to respective ones of outputs 74. In principle, memory for one configuration bit suffices to select between these two modes, but preferably memory for additional configuration bits is provided that select which of the inputs are copied to all of the programmable logic units in the random logic mode. In the latter case, five configuration bits may be used: one configuration bit for selecting between the multi-bit operand mode (one to one signal transfer) and the random logic mode (four times copying) and two times two configuration bits, each for selecting one of four of inputs that is coupled to inputs of each of the programmable logic units.

The third multiplexers (not shown) select the inputs from which signals are fed to the control inputs of the stages of the multiplexers in output circuit 26. Preferably, two third multiplexers are provided, each for selecting an input signal for controlling a respective stage of output circuit 26.

In principle the signal inputs of the cell may be organized into groups of (e.g. four) signal inputs in which each signal input of a group supplies a respective bit of a multi-bit operand that corresponds to the group. To support a random logic mode and a multi-bit operand mode it suffices that the cell has a configuration bit that selects between passing input signals from pairs of groups of logic inputs, each programmable logic unit receiving signals from both groups in the pair, and passing copies of a set of inputs to all programmable logic units. Additional configuration bits may be provided to select the groups or the set.

In this context, a cell with four programmable logic units is especially advantageous, because the number of input signals of random logic functions and the number of bits in multi-bit operands is the same in this case. This means that each group that corresponds to an operand can also be selected as a set of inputs for a random logic function. The configuration bits, if any, for selecting the groups in the multi-bit operand modes may be used to select a group in the random logic mode. In this case a single additional configuration bit suffices for use in the random logic mode, to select which of the groups that would be used as operands in the multi-bit operand mode will be used as set of inputs for the random logic function.

As will be appreciated, the cell described in the preceding, when used in an programmable logic circuit, makes it possible to configure the circuit to perform a multi-bit operand signal processing operation that involves carry signals between different bit levels and a four bit input random logic function. Configuration of two three bit input random logic functions may be supported as well. A small number of configuration bits suffices to select the mode of operation. Sixteen configuration bits suffice to define both the four bit input random logic function and the multi-bit signal processing operation.

However, it will be appreciated that many variations are possible in cell 20 that enable a similar configurability. For example, cells with larger number of two bit input programmable logic units 24a-d may be used, for example with eight such units and with a multiplexer that selects the output of one of these eight programmable logic units under control of three input signals. Thus, 8 bit multi-bit signal processing operations may be used for example.

1. An electronic circuit with an array of programmable logic cells, each of the cells comprising
an input circuit with a plurality of logic inputs;
an output circuit;
a carry input and a carry output, a carry chain coupled between the carry input, the input circuit and the carry output;
a plurality of programmable logic units, coupled in parallel between the input circuit and the output circuit, the input circuit being configurable between a random logic mode in which each of the programmable logic units receives logic input signals from the same combination of the logic inputs, and a multi-bit operand processing mode in which each of the programmable logic units receives logic input signals from different ones of the logic inputs, the programmable logic units being coupled to successive positions along the carry chain at least in the multi-bit operand mode, so as to process carry signals from the carry chain, the output circuit selecting an output signal from the programmable logic units under control of further input signals in the random logic mode and passing outputs from the programmable logic units in parallel in the multi-bit operand mode.

2. An electronic circuit according to claim 1, wherein at least one of the programmable logic units comprises
a configurable look-up table circuit, having an output and inputs coupled to receive the logic input signals from the input circuit;
a controllable inverter/non-inverter circuit, the output of the look-up table circuit being coupled to the output circuit via the inverter/non-inverter circuit, a carry output of the carry chain being coupled to an inversion non-inversion control input of the inverter/non-inverter circuit.

3. An electronic circuit according to claim 1, wherein the cell comprises a subtraction control circuit arranged to control at least a carry output determination operation of the carry chain, the carry chain determining a carry output signal from input signals and carry input signals at each position along the carry chain, control by the subtraction control circuit switching the carry output determination at least between a determination appropriate for addition and determination appropriate for subtraction, under control of a subtraction control signal.

4. An electronic circuit according to claim 1, wherein the cell comprises a respective multiplication circuit for each programmable logic unit, coupled to multiply at least one of the inputs signals of the programmable logic unit with a multiplicand prior to supplying said at least one of the input signals to an input of the programmable logic unit.

5. An electronic circuit according to claim 1, wherein each of the programmable logic units has two unit inputs for signals from the logic inputs, each programmable logic unit being configurable to implement independently any two-input bit logic function of the logic inputs.

6. An electronic circuit according to claim 1, wherein the carry chain circuit has a configurable coupling between said positions and a the carry input of the cell, for configurably supplying either a carry input signal to the carry chain or a standard signal, under control of configuration information from a configuration memory.

7. An electronic circuit according to claim 1, wherein the carry chain circuit has a plurality of configurable couplings, each coupled between a respective one of said positions and a respective one of the programmable logic units, for configurably supplying either a carry signal from said position to the programmable logic circuit or a further signal that is not a result of propagation through the carry chain, under control of configuration information from a configuration memory.

8. An electronic circuit according to claim 7, wherein each of the programmable logic units comprises
a configurable look-up table circuit, having an output and inputs coupled to receive the logic input signals from the input circuit;
a controllable inverter/non-inverter circuit, the output of the look-up table circuit being coupled to the output circuit via the inverter/non-inverter circuit, the configurable coupling being coupled to an inversion non-inversion control input of the inverter/non-inverter circuit;
an exclusive OR circuit, with inputs coupled to inputs of the programmable logic unit and an output configurably coupled to supply the further signal subject to assertion of a multiplex control signal that is common to the programmable logic units.

9. An electronic circuit according to claim 1, wherein the input circuit is arranged to be configurable to provide only a proper subset of all possible couplings between the signal inputs of the cell and inputs of the programmable logic units, the subset comprising a multi-bit operand coupling, in which respective ones of the signal inputs are coupled to respective inputs of respective ones of the programmable logic units, and a random logic coupling in which a subset of the signal inputs is coupled to the inputs of each of the programmable logic units.

10. An electronic circuit according to claim 7, wherein the subset comprises a two-bit output random logic coupling in which a first and second subset of the signal inputs are coupled to the inputs of each of a first and second subset of pluralities of the programmable logic units respectively.

11. An electronic circuit according to claim 1, configured to perform a random logic function, wherein each of the programmable logic units is configured to provide a respective input-output relation and logic input signals from the logic inputs select from which of the programmable logic units a logic output signal is passed to a logic output of the output circuit.

12. An electronic circuit according to claim 1, configured to perform a multi-bit operand signal processing function, wherein each of the programmable logic units is configured to provide the same input-output relation subject to a carry input signal from the carry chain, and the output circuits outputs output signals from the programmable logic units in parallel.

13. An electronic circuit according to claim 1, configured to perform a multiplexing function, wherein each of the programmable logic units is configured to pass one of its input signals to an output, and to invert that one of the input signals during said passing when a multiplexer control signal that is common to the programmable logic units is asserted and the input signals of the programmable logic unit are mutually different.
